(19) United States
(12) Patent Application Publication
(10) Pub. No.: US 2010/0246143 A1
(43) Pub. Date: Sep. 30, 2010

(54) Electromagnetic Interference Shielding for Compact Electronic Devices

(76) Inventors: Richard Hung Minh Dinh, Cupertino, CA (US); Andrew Just, San Francisco, CA (US); Dennis Pyper, San Jose, CA (US); Hugo Fiennes, Palo Alto, CA (US); Scott Myers, San Francisco, CA (US); Erik Wang, Redwood City, CA (US); Ron Dimpflmaier, Los Gatos, CA (US)

Correspondence Address: TI Law Group, 2055 Junction Avenue, #205, San Jose, CA, 95131-2116, US

(21) Appl. No.: 12/412,263

(22) Filed: Mar. 26, 2009

(51) Int. Cl. H05K 7/00; H05K 9/00; H05K 13/04

(52) U.S. Cl. 361/748; 361/818; 29/729

(57) ABSTRACT

Improved approaches for providing electromagnetic interference shielding to one or more electrical components within a housing of a portable electronic device are disclosed. According to one aspect of certain embodiments, an electromagnetic shield can be attached to one or more edges of a substrate (e.g., printed circuit board) provided within a housing of a portable electronic device. Advantageously, this allows the substrate space to be efficiently utilized such that relatively wide electrical components can be provided on the substrate without having to further increase the width of the substrate to provide space for an EMI shielding structure and its attachment to the substrate. The housing of the portable electronic device can be compact, such as a low profile housing.

### BACKGROUND OF THE INVENTION

Electromagnetic interference (EMI) is an unwanted disturbance that affects an electrical device due to either electromagnetic conduction or electromagnetic radiation emitted from an external source. The disturbance may interrupt, obstruct, or otherwise degrade or limit the effective performance of the electrical device. EMI can also be referred to as radio frequency interference (RFI). The Federal Communications Commission (FCC) has developed standards for EMI immunity for consumer electronic devices.

Electromagnetic shielding can be used to limit the penetration of electromagnetic fields into a space by blocking them with a barrier made of conductive material. Typically, the barrier is implemented as an enclosure that separates electrical devices from the outside world. Electromagnetic shielding used to block radio frequency electromagnetic radiation is also known as RF shielding. Typical materials used for electromagnetic shielding include sheet metal, metal mesh, and metal foam. Any holes in the shield must be significantly smaller than the wavelength of the radiation that is being kept out, or the enclosure will not be effective.

Conventionally, certain electrical components on a printed circuit board within a portable electronic device housing are often EMI shielded to reduce EMI emissions and/or EMI disruptions. The EMI shielding is conventionally done with an EMI can (or RF can) that is a metal container that is placed over the certain electrical components and mounted onto the surface of the printed circuit board. Often, the EMI shield is made from a metal sheet having openings or from a metal mesh. The openings can allow thermal heat to better dissipate through the EMI shield. Unfortunately, however, as compact portable electronic devices become increasingly more compact, the availability of space within a housing for a compact electronic device becomes more limited. Accordingly, given the constrained geometries and tight tolerances of compact portable electronic devices, such as handheld portable electronic devices, it is increasingly difficult to provide EMI shielding without causing a significant area increase penalty to housing designs for compact electronic devices.

Thus, there is a need for improved techniques for providing EMI shielding to one or more electrical components within a housing of a portable electronic device.

### SUMMARY OF THE INVENTION

The invention pertains to improved approaches for providing electromagnetic interference (EMI) shielding to one or more electrical components within a housing of a portable electronic device. According to one aspect of certain embodiments of the invention, an electromagnetic shield can be attached to one or more edges of a substrate (e.g., printed circuit board) provided within a housing of a portable electronic device. Advantageously, this allows the substrate space to be efficiently utilized such that relatively wide electrical components can be provided on the substrate without having to further increase the width of the substrate to provide space for an EMI shielding structure and its attachment to the substrate. The housing of the portable electronic device can be compact, such as a low profile housing.

The invention may be implemented in numerous ways, including, but not limited to, as a system, device, apparatus, or method. Example embodiments of the present invention are discussed below.

As an electronic apparatus, one embodiment of the invention can, for example, include at least: a substrate having a top surface, a bottom surface and a plurality of side surfaces, the substrate being configured to support one or more electronic components coupled to the top surface or the bottom surface; and a metal structure secured proximate to the top surface or the bottom surface of the substrate over and around at least one of the one or more electronic components, wherein at least one side of the metal structure is attached to a corresponding at least one side surface of the side surfaces of the substrate.

As an electronic device, one embodiment of the invention can, for example, include at least: a printed circuit board (PCB), the PCB having a plurality of layers, and the PCB having a top surface, a bottom surface and a plurality of side surfaces; at least one electrical component mounted on the top surface the PCB; and an electromagnetic interference (EMI) shield mounted on the top surface of the PCB over and around the at least one electrical component, wherein at least one side of the EMI shield is attached to at least one corresponding side surface of the side surfaces of the PCB.

As a method for providing electromagnetic interference (EMI) shielding for an electronic device, one embodiment of the invention can, for example, include at least the acts of: forming or obtaining an EMI shield having at least a top surface and a plurality of side surfaces; receiving a substrate having at least one electrical component mounted thereon that is to be EMI shielded; and attaching the EMI shield to the substrate over and around the at least one electrical component with respect to the substrate, such that at least one side surface of the EMI shield connects to a corresponding side of the substrate.

Various aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, in which:

FIG. 1 is a simplified perspective view of an electromagnetic interference (EMI) shielding arrangement according to one embodiment of the invention.

FIG. 2A is a flow diagram of an assembly process according to one embodiment of the invention.

FIG. 2B is a flow diagram of a shield attachment process according to one embodiment of the invention.

FIG. 3A illustrates a sectional top view of a portable electronic device according to one embodiment of the invention.

FIG. 3B illustrates a sectional top view of a portable electronic device according to one embodiment of the invention.

FIG. 3C is a sectional side view of the portable electronic device illustrated in FIG. 3B.

FIG. 4A illustrates a sectional top view of a portable electronic device according to one embodiment of the invention.

FIG. 4B illustrates a sectional top view of a portable electronic device according to one embodiment of the invention.

FIG. 4C is a sectional side view of the portable electronic device illustrated in FIG. 4B.

FIG. 5A is a perspective view of a printed circuit board assembly according to one embodiment of the invention.

FIG. 5B is a sectional side view of the printed circuit board assembly illustrated in FIG. 5A.

### DETAILED DESCRIPTION OF THE INVENTION

The invention pertains to improved approaches for providing electromagnetic interference shielding to one or more electrical components within a housing of a portable electronic device. According to one aspect of certain embodiments of the invention, an electromagnetic shield can be attached to one or more edges of a substrate (e.g., printed circuit board) provided within a housing of a portable electronic device. Advantageously, this allows the substrate space to be efficiently utilized such that relatively wide electrical components can be provided on the substrate without having to further increase the width of the substrate to provide space for an EMI shielding structure and its attachment to the substrate.

The housing of the portable electronic device can be compact, such as a low profile housing. The portable electronic device can pertain to a portable digital media player, a mobile telephone, personal digital assistant, handheld computing devices, etc.

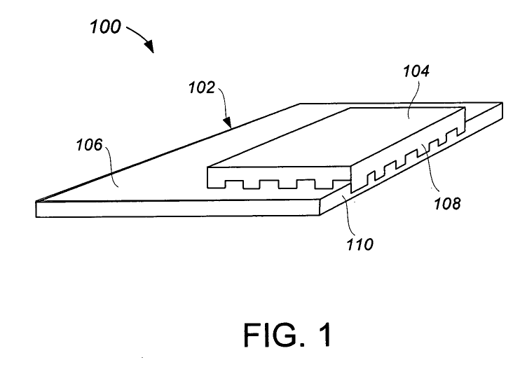

Embodiments of the invention are discussed below with reference to FIGS. 1-5B. However, those skilled in the art will readily appreciate that the detailed description given herein with respect to these figures is for explanatory purposes as the invention extends beyond these limited embodiments.

FIG. 1 is a simplified perspective view of an electromagnetic interference (EMI) shielding arrangement 100 according to one embodiment of the invention. The EMI shielding arrangement 100 includes a substrate 102 and an EMI shielding structure 104. The EMI shielding arrangement 100 is provided over at least a portion of the substrate 102 to provide EMI shielding to electrical components that are attached to the substrate 102. For example, the substrate 102 can be a Printed Circuit Board (PCB) having one or more electrical devices mounted thereon that are to be EMI shielding using the EMI shielding structure 104. Accordingly, the EMI shielding structure 104 can be place over the one or more electrical devices mounted thereon that are to be EMI shielded. As one example, the EMI shielding structure 104 can pertain to an EMI shielding can (also known as a RF can). The EMI shielding structure 104 can be formed from an electrically conductive material, such as sheet metal or mesh metal. The EMI shielding structure 104 is also electrically and mechanically attached to the substrate 102. In one implementation, the EMI shielding structure 104 is attached to ground pads or traces at various points on the substrate 102. For example, at the interface between the substrate 102 and the EMI shielding structure 104 can be coupled to ground every three (3) millimeters or less.

According to one embodiment, when the EMI shielding structure 104 is attached to a surface 106 (e.g., top surface) of the substrate 102, at least one side 108 of the EMI shielding structure 104 is placed against a corresponding side surface 110 of the substrate 102. Advantageously, the substrate 102 does not have to made larger to accommodate the EMI shielding. As a result, the substrate 102 can be thinner than would be conventionally provided since surface space on the surface 106 of the substrate 102 need not be provided for placing and attaching the side 108 of the EMI shielding structure 104 to the surface 106 of the substrate 102.

The EMI shielding arrangement 100 is well suited for use with portable electronic devices and, more particularly, compact portable electronic devices. For example, the compact portable electronic device can be a handheld electronic device. A housing for a compact portable electronic device housing tends to be internally filled with high density construction, such that there is very little unoccupied space. The housing for the portable electronic device can be of any material or combination of materials, such as metals, plastics, or ceramics.

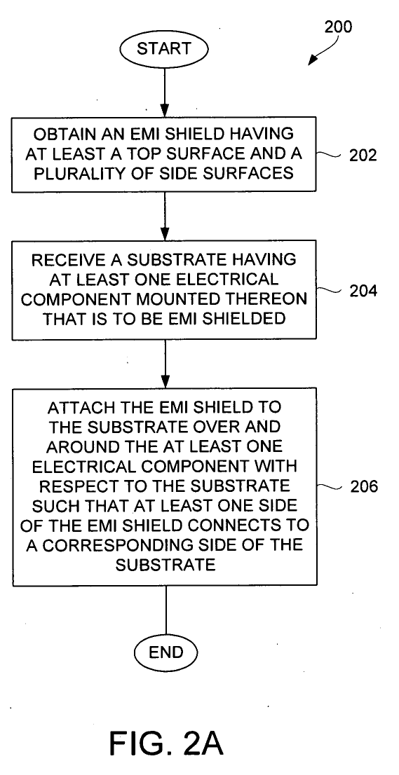

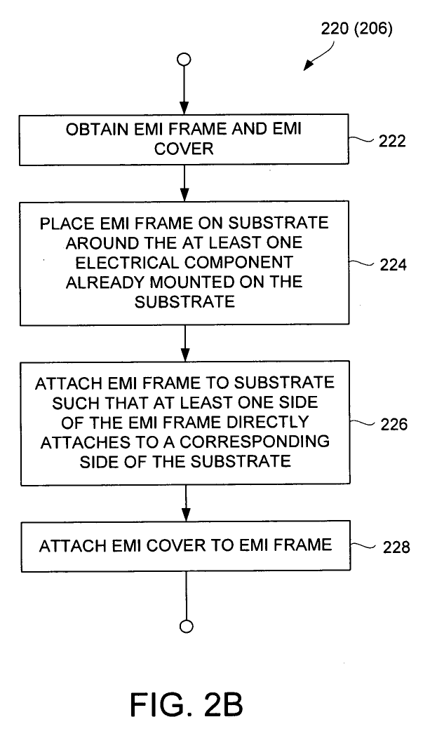

FIG. 2A is a flow diagram of an assembly process 200 according to one embodiment of the invention. The assembly process 200 represents part of an overall assembly of an electronic device. In particular, the assembly process 200 represents processing associated providing electromagnetic interference shielding to a compact electronic device. In other words, the assembly process 200 is able to provide electromagnetic shielding to a compact electronic device in a space efficient manner.

The assembly process 200 can initially obtain 202 an EMI shield having at least a top surface and a plurality of side surfaces. In one implementation, the EMI shield is a can like structure having a top surface and four sides. Next, a substrate can be received 204. In one implementation, the substrate can include a top surface, a bottom surface, and a plurality of side surfaces. The substrate can have at least one electrical component that is to be EMI shielded mounted on the top surface of the substrate. Examples of electrical components that may require shielding are integrated circuits, transistors, capacitors, inductors, etc.

Thereafter, the EMI shield can be attached 206 to the substrate over and around the at least one electrical component with respect to the substrate. Typically, the EMI shield together with the substrate enclose the at least one electrical component. Here, the EMI shield is attached 206 such that at least one side of the EMI shield connects to a corresponding side of the substrate. Those sides of the EMI, if any, that are not attached to the sides of the EMI shield can be attached 206 to the top surface of the substrate. After the EMI shield has been attached 206, the assembly process 200 can end since the EMI shield has been attached 206. Other processing (not shown) can then be performed to further assemble the electronic device.

FIG. 2B is a flow diagram of a shield attachment process 220 according to one embodiment of the invention. The shield attachment process 220 is, for example, one suitable implementation for the block 206 illustrated in FIG. 2B. The shield attachment process 220 initially obtains 222 an EMI frame and an EMI cover that together are used to form the EMI shield. Next, the EMI frame can be placed 224 on the substrate around the at least one electrical component already mounted on the substrate. Typically, the EMI frame will be placed 224 around all of the electrical components on the substrate that are to be EMI shielded. Thereafter, the EMI frame can be attached 226 to the substrate. In particular, the EMI frame can be attached 226 to the substrate such that at least one side of the EMI frame directly attaches to a corresponding side of the substrate. Those sides, if any, of the EMI frame that do not attach directly to a corresponding side of the substrate can be attached to the top surface of the substrate. After the EMI frame has been attached 226, the EMI cover can be attached 228 to the EMI frame. At this point, the EMI shield has been properly attached to the substrate and provides the appropriate electromagnetic shielding for the one or more electrical components that is encloses.

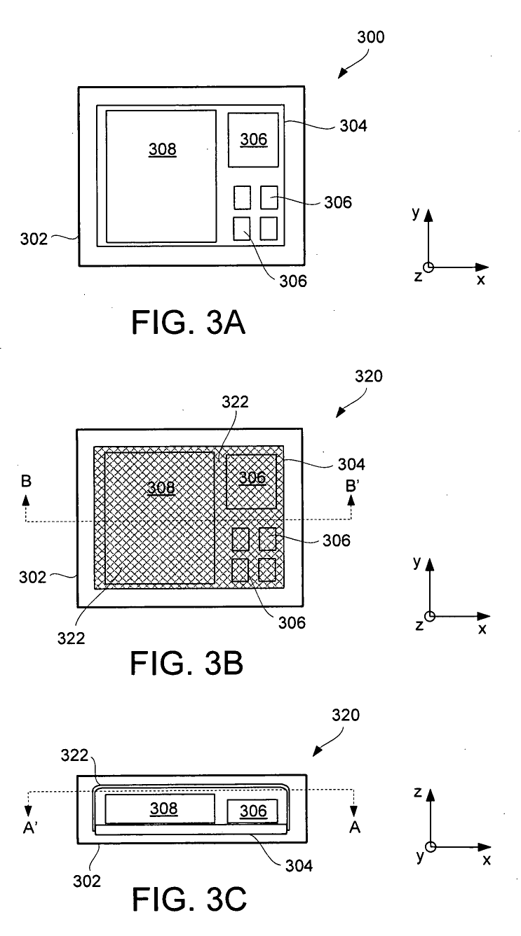

FIG. 3A illustrates a sectional top view of a portable electronic device 300 according to one embodiment of the invention. The portable electronic device 300 is a compact portable electronic device, such as a handheld electronic device. The sectional top view pertains to reference line A-A′ shown in FIG. 3C, which reflects a view internal to the housing 302 (with no EMI shield 322). The portable electronic device 300 has a housing 302. Within the housing 302 is a substrate 304. On the substrate 304 are mounted one or more electrical components 306 and 308. As an example, the substrate 304 can be a printed circuit board. The one or more electrical components 306 and 308 can, for example, pertain to integrated circuits, transistors, resistors, inductors, capacitors and the like. Of the electrical components 306 and 308, the one or more electrical components 306 represent those electrical components that comfortably fit on the substrate 304, and the one or more electrical components 308 represent those electrical components that fit on the substrate 304 with not much clearance. In other words, as illustrated in FIG. 3A, the electrical component 308 is nearly as wide as the width of the substrate 304, whereas the width of the electrical components 306 is considerably less than the width of the substrate 304.

FIG. 3B illustrates a sectional top view of a portable electronic device 320 according to one embodiment of the invention. The portable electronic device 320 is a compact portable electronic device similar to the portable electronic device 300 illustrated in FIG. 3A. As such, the portable electronic device 322 has the substrate 304 within the housing 302. The one or more electrical components 306 and 308 are mounted on the substrate 304. Furthermore, as illustrated in FIG. 3B, the portable electronic device 320 further includes an EMI shield 322 within the housing 302. In general, the EMI shield 322 is provided over at least a portion of the substrate 304 to provide EMI shielding with respect to the electrical components 306 and 308 mounted on the substrate 304. In the embodiment illustrated in FIG. 3B, the EMI shield 322 fits over the entire substrate 304. However, in other embodiments, the EMI shield 322 need only fit over a portion of the substrate 304.

Advantageously, to support a compact, low profile design for the housing 302 of the portable electronic device 320, the EMI Shield 322 can fit over and couple to one or more sides of the substrate 304. More particularly, in the case of the electrical component 308 there is insufficient space between the edge of the electrical component 308 and the edge of the associated side of the substrate 304 to attach the EMI shield 322 on the top surface of the substrate 304. Hence, for at least one side of the substrate 304 where there is insufficient space on the top surface of the substrate 304, the EMI Shield 322 can fit over and couple to a corresponding side of the substrate 304.

FIG. 3C is a sectional side view of the portable electronic device 320 illustrated in FIG. 3B. The sectional side view pertains to reference line B-B′ shown in FIG. 3B. The portable electronic device 320 as illustrated in FIG. 3C shows the EMI shield 322 being provided over the electrical components 306 and 308 and coupling to the sides of the substrate 304. With this design, the size of the substrate 304 is able to remain smaller at each of the sides where the EMI shield 322 couples to those sides. While the amount by which the substrate 304 can remain smaller through use of the invention is relatively small, the savings directly correlates to a resulting portable electronic device housing that is more compact.

In the embodiment illustrated in FIGS. 3B and 3C, the EMI shield 322 fits over and couples to all four sides of the substrate 304. However, more generally, the EMI shield 322 can fit over and couple to one or more of the sides of the substrate 304. For example, as shown in FIG. 1, the EMI shielding structure 104 couples to one side surface 110 of the substrate 102 and otherwise couples to the top surface of the substrate 102.

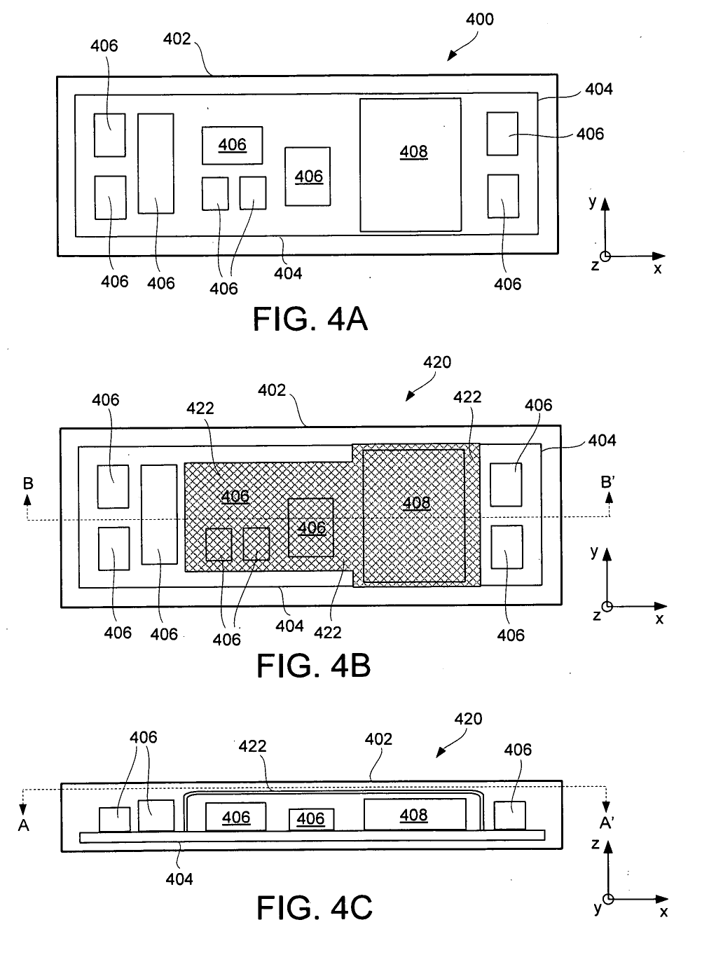

FIG. 4A illustrates a sectional top view of a portable electronic device 400 according to one embodiment of the invention. The portable electronic device 400 is a compact portable electronic device, such as a handheld electronic device. The sectional top view pertains to reference line A-A′ shown in FIG. 4C, which reflects a view internal to the housing 402 (with no EMI shield 422). The portable electronic device 400 has a housing 402. Within the housing 402 is a substrate 404. On the substrate 404 are mounted one or more electrical components 406 and 408. As an example, the substrate 404 can be a printed circuit board. The one or more electrical components 406 and 408 can, for example, pertain to integrated circuits, transistors, resistors, inductors, capacitors and the like. Of the electrical components 406 and 408, the one or more electrical components 306 represent those electrical components that comfortably fit on the substrate 404, and the one or more electrical components 408 represent those electrical components that fit on the substrate 404 with not much clearance. In other words, as illustrated in FIG. 3A, the electrical component 408 is nearly as wide as the width of the substrate 404, whereas the width of the electrical components 406 is considerably less than the width of the substrate 404.

FIG. 4B illustrates a sectional top view of a portable electronic device 420 according to one embodiment of the invention. The portable electronic device 420 is a compact portable electronic device similar to the portable electronic device 400 illustrated in FIG. 4A. As such, the portable electronic device 422 has the substrate 404 within the housing 402. The one or more electrical components 406 and 408 are mounted on the substrate 404. Furthermore, as illustrated in FIG. 4B, the portable electronic device 420 further includes an EMI shield 422 within the housing 402. The EMI shield 422 is typically a metal structure, such as a can, that fits over electrical components. For example, the EMI shield 422 can be formed from a metal sheet or a metal mesh. In general, the EMI shield 422 is provided over at least a portion of the substrate 404 to provide EMI shielding with respect to the electrical components 406 and 408 mounted on the substrate 404. In the embodiment illustrated in FIG. 4B, the EMI shield 422 fits over a central portion of the substrate 404.

To support a compact, low profile design for the housing 402 of the portable electronic device 420, the EMI shield 422 can fit over and couple to portions of two sides of the substrate 404 in the vicinity of the electrical component 408. Here, in the case of the electrical component 408 there is insufficient space between the edge of the electrical component 408 and the edge of the associated side of the substrate 404 to attach the EMI shield 422 on the top surface of the substrate 404. Hence, for the two sides of the substrate 404 where there is insufficient space on the top surface of the substrate 404 to attach the EMI shield 422 on the top surface of the substrate, the EMI shield 422 can fit over and couple to the corresponding sides of the substrate 404. However, on all of the other sides (or portions thereof), the EMI shield 422 can be attached to the top surface of the substrate 404 since there is space on the top surface of the substrate 404.

FIG. 4C is a sectional side view of the portable electronic device 420 illustrated in FIG. 4B. The sectional side view pertains to reference line B-B′ shown in FIG. 4B. The portable electronic device 420 as illustrated in FIG. 4C shows the EMI shield 422 being provided over certain of the electrical components 406 and 408 and coupling to portions of two of the sides of the substrate 404. With this design, the size of the substrate 404 is able to remain smaller at each of the sides where the EMI shield 422 couples to those sides. While the amount by which the substrate 404 can remain smaller through use of the invention is relatively small, the savings directly correlates to a resulting portable electronic device housing that is more compact. While the size of the resulting portable electronic device can vary with implementation, in one implementation the resulting portable electronic device is handheld with a thickness of not more than 10 millimeters.

In the various embodiments noted above, an EMI shield can connect to a primary (e.g., top or bottom) surface of a substrate (e.g., printed circuit board). Alternatively or additionally, the EMI shield can attach to one or more side surfaces of the substrate. The connections between the EMI shield and the substrate can be solder connections. For example, at predetermined intervals the sides of the EMI shield can be connected to the top, bottom or side surface of the substrate. In the case where the EMI shield is attached to the sides, at least one electrical component can be placed very close to the edge of the substrate. In one example, the at least one electrical component can be placed within not more than 0.7 millimeters from the nearest edge of the substrate. In another example, the at least one electrical component can be placed within 0.2-1.0 millimeters from the nearest edge of the substrate.

Given that layout of electrical components and EMI shields on substrates (e.g., printed circuit boards) is subject to minimum spacings, conventionally the electrical components are placed more than 1.2 millimeter in from each board edge when EMI shielding is provided by a EMI shielding can attached to the top surface of the substrate. As a result, use of EMI shielding conventionally results in use of wider circuit boards. The wider circuit boards cause the resulting electronic device to be wider. In contrast, with several embodiments of the invention, the minimum spacings are substantially reduced where the EMI shield can attaches to the side surface of the substrate. For example, the electrical components can be placed at about 0.5 millimeters in from each board edge when EMI shielding is provided by an EMI shielding can be attached to a side surface of the substrate. Hence, in this example, the invention can provide a savings is about 0.5 millimeters at each of the edges where the EMI shielding attaches to a side surface of the substrate. For example, with two sides of the EMI shield can being attached to the side surface of the substrate, the space savings provided by the invention is about 1.0 millimeters.

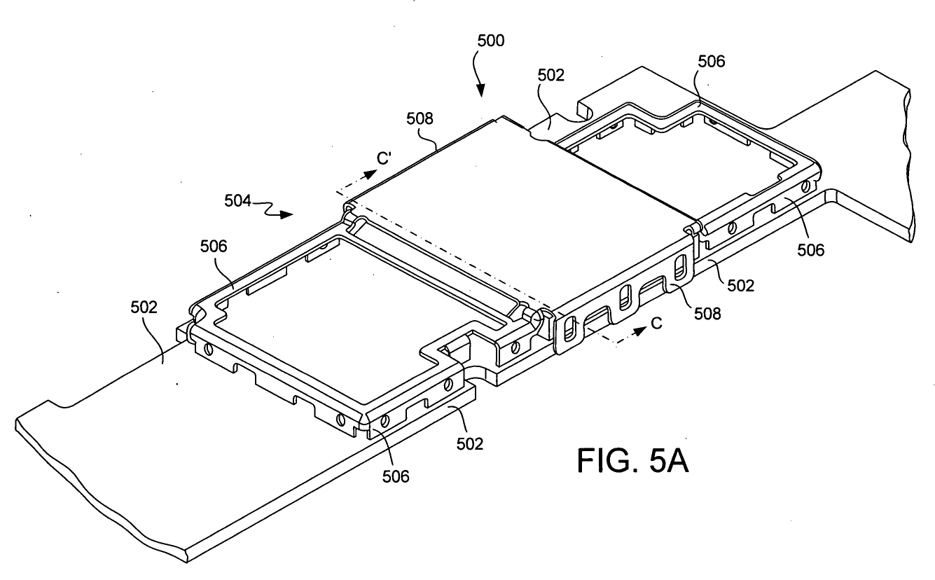

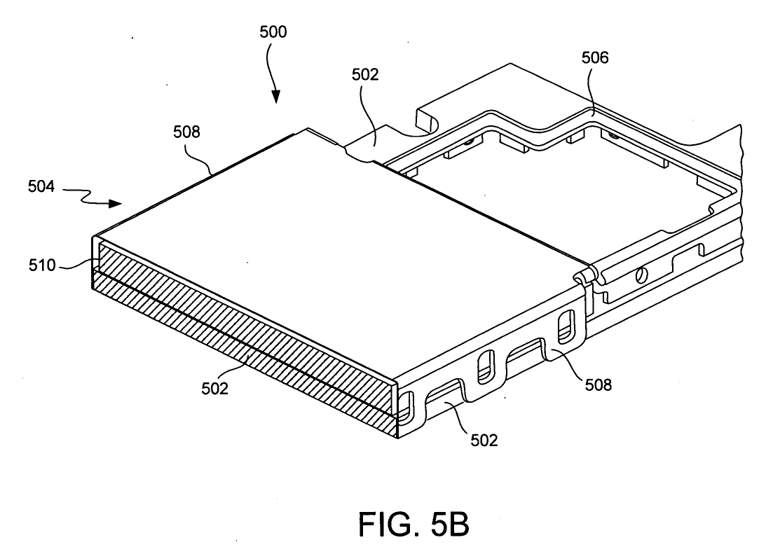

FIG. 5A is a perspective view of a printed circuit board assembly 500 according to one embodiment of the invention. The printed circuit board assembly 500 in a printed circuit board 502 and an integrated frame and lid arrangement 504. The integrated frame and lid arrangement 504 is attached to the printed circuit board 502. The integrated frame and lid arrangement 504 includes a frame 506 and a lid 508. In the embodiment illustrated in FIG. 5A, the frame 506 is attached to the printed circuit board 502. For example, the frame 506 can be soldered to the printed circuit board 502. The top surface of the printed circuit board 502 can include solder pads to the bottom of the fame 500 can be soldered. In one implementation, the frame 506 can be soldered to the solder pads on the top surface of the printed circuit board 502 at predetermined intervals, such as every 3 millimeters. The solder pads are in turn connected to ground (e.g., a ground plane of the printed circuit board 502).

The lid 508 is attached to or integral with the frame 506. In the embodiment shown in FIG. 5A, the lid 508 is provided at the central portion of the frame 506. However, in other embodiment, the lid 508 can be connected to an portion or all of the frame 506. The lid 508 is also wider than the frame 506 and extends below the top surface of the printed circuit board 502 so as to attach to the side of the printed circuit board 502. For example, the lid 508 can be soldered to corresponding sides of the printed circuit board 502. In one implementation, one or more sides of the lid 508 can be soldered to a plated side of the printed circuit board 502. For example, one or more sides of the lid 508 can be soldered to a plated side of the printed circuit board 502 at predetermined intervals, such as every 3 millimeters. The plated one or more sides of the printed circuit board 502 are in turn connected to ground (e.g., a ground plane of the printed circuit board 502). Although not shown in FIG. 5B, one or more caps (tops or lids) would be placed on the frame 506, to from a top shielding surface over those portions of the frame 506 not having the lid 508. The caps can be attached to the frame 506 by solder, adhesive or other means.

FIG. 5B is a sectional side view of the printed circuit board assembly 500 illustrated in FIG. 5A. The sectional side view pertains to reference line C-C′ shown in FIG. 5A. The printed circuit board assembly 500 illustrated in FIG. 4B shows the lid 508 covering a wide electrical component 510 (e.g., integrated circuit) that has a width that is substantially the width of the printed circuit board 502. Hence, in the central region of the of the frame 506, the lid 508 is integrated with the frame 506 and extends across the full with of the printed circuit board 502 so as to cover (and thus shield) the electrical component 510. As shown in FIG. 5B, at the two sides where the lid 508 extends across the full width of the printed circuit board 502, the lid couples to the corresponding sides of the printed circuit board 502.

With this design, the width of the printed circuit board 502 is able to remain smaller at the central portion of the frame 506 since the lid 508 extends across the full width of the printed circuit board 502 and is able to couple to the corresponding sides of the printed circuit board. Consequently, EMI shielding is provided to those one or more electrical components (including the electrical component 510) attached to the printed circuit board 502 that are now covered by the integrated frame and lid arrangement 504 together with one or more caps.

A portable electronic device as discussed herein may be a hand-held electronic device. The term hand-held generally means that the electronic device has a form factor that is small enough to be comfortably held in one hand. A hand-held electronic device may be directed at one-handed operation or two-handed operation. In one-handed operation, a single hand is used to both support the device as well as to perform operations with the user interface during use. In two-handed operation, one hand is used to support the device while the other hand performs operations with a user interface during use or alternatively both hands support the device as well as perform operations during use. In some cases, the hand-held electronic device is sized for placement into a pocket of the user. By being pocket-sized, the user does not have to directly carry the device and therefore the device can be taken almost anywhere the user travels.

The advantages of the invention are numerous. Different embodiments or implementations may, but need not, yield one or more of the following advantages. One advantage of certain embodiments of the invention is that electrical components within a portable electronic device housing can be EMI shielded in a space efficient manner. As a result, portable electronic devices can be thin and compact. Another advantage of certain embodiments of the invention is that EMI shields can be attached to one or more sides of a substrate. Advantageously, substrates internal to portable electronic device housings can be made smaller and more compact when EMI shielding can be attached to a side surface as opposed to a top surface of the substrate.

The various aspects, features, embodiments or implementations of the invention described above can be used alone or in various combinations.

The many features and advantages of the present invention are apparent from the written description. Further, since numerous modifications and changes will readily occur to those skilled in the art, the invention should not be limited to the exact construction and operation as illustrated and described. Hence, all suitable modifications and equivalents may be resorted to as falling within the scope of the invention.

What is claimed is:

1. An electronic apparatus comprising:
a substrate having a top surface, a bottom surface and a plurality of side surfaces, the substrate being configured to support one or more electronic components coupled to the top surface or the bottom surface; and
a metal structure secured proximate to the top surface or the bottom surface of the substrate over and around at least one of the one or more electronic components,
wherein at least one side of the metal structure is attached to a corresponding at least one side surface of the side surfaces of the substrate.

2. An electronic apparatus as recited in claim 1, wherein the at least one side surface of the metal structure is attached to the corresponding at least one side surface of the side surfaces of the substrate by way of one or more solder connections.

3. An electronic apparatus as recited in claim 1, wherein at least one other side surface of the metal structure is attached to the top surface or the bottom surface of the substrate.

4. An electronic apparatus as recited in claim 3, wherein the at least one other side surface of the metal structure is attached to the top surface or the bottom surface of the substrate by way of one or more solder connections.

5. An electronic apparatus as recited in claim 3, wherein the at least one other side surface of the metal structure is attached to the top surface or the bottom surface of the substrate by way of one or more mechanical members.

6. An electronic apparatus as recited in claim 3, wherein another side of the metal structure is attached to a corresponding another side surface of the side surfaces of the substrate.

7. An electronic apparatus as recited in claim 1, wherein the metal structure has four sides, two of the sides of the metal structure are attached to corresponding to ones of the side surfaces of the substrate, and two of the sides of the metal structure are attached to the top surface or the bottom surface of the substrate.

8. An electronic apparatus as recited in claim 1, wherein the metal structure has a thinner section and a wider section, wherein the thinner section is affixed to the top or bottom surface of the substrate, and wherein the wider section is affixed to at least one of the side surfaces of the substrate.

9. An electronic apparatus as recited in claim 1, wherein said electronic device is a compact electronic device with a low profile.

10. An electronic apparatus as recited in claim 9, wherein said electronic device has a thickness of not more than 10 millimeters.

11. An electronic apparatus as recited in claim 1, wherein the metal structure is an electromagnetic interference (EMI) shielding can.

12. An electronic apparatus as recited in claim 11, wherein at least one of the electronic components connected to the substrate and covered by the EMI shielding can is placed within not more than 0.7 millimeters from the nearest edge of the substrate.

13. An electronic apparatus as recited in claim 11, wherein at least one of the electronic components connected to the substrate and covered by the EMI shielding can is placed within 0.2-1.0 millimeters from the nearest edge of the substrate.

14. An electronic device comprising:
a printed circuit board (PCB), the PCB having a plurality of layers, and the PCB having a top surface, a bottom surface and a plurality of side surfaces;
at least one electrical component, the at least one electrical component being mounted on the top surface the PCB; and
an electromagnetic interference (EMI) shield, the EMI shield being mounted on the top surface of the PCB over and around the at least one electrical component,
wherein at least one side of the EMI shield is attached to at least one corresponding side surface of the side surfaces of the PCB.

15. An electronic device as recited in claim 14, wherein the electronic device is a handheld mobile electronic device.

16. An electronic device as recited in claim 14, wherein the at least one corresponding side surface of the PCB is at least partially covered with a conductive metal, and wherein the at least one side of the EMI shield is connected to the conductive metal at the at least one corresponding side surface of the PCB.

17. An electronic device as recited in claim 16, wherein the PCB is a multi-layer printed circuit board, and wherein at least one of the layers of the PCB is a ground layer, and wherein the conductive metal provided at the at least one corresponding side surface of the PCB is connected to the ground layer.

18. A method for providing electromagnetic interference (EMI) shielding for an electronic device, said method comprising:
forming or obtaining an EMI shield having at least a top surface and a plurality of side surfaces;
receiving a substrate having at least one electrical component mounted thereon that is to be EMI shielded; and
attaching the EMI shield to the substrate over and around the at least one electrical component with respect to the substrate, wherein said attaching connects at least one side surface of the EMI shield to a corresponding side of the substrate.

19. A method as recited in claim 18, wherein the corresponding side of the substrate is plated with a conductive metal, and wherein said attaching connects at least one side surface of the EMI shield to the conductive metal at the corresponding side of the substrate.

20. A method as recited in claim 18, wherein the substrate is a multi-layer printed circuit board, and wherein at least one of the layers of the substrate is a ground layer, and wherein the conductive metal plated to the corresponding side of the substrate is connected to the ground layer.
